(19) United States
(12) Patent Application Publication
(10) Pub. No.: US 2017/0040414 A1
(43) Pub. Date: Feb. 9, 2017

(54) SEMICONDUCTOR DEVICE

(71) Applicant: Kabushiki Kaisha Toshiba, Tokyo (JP)

(72) Inventor: Wataru Saito, Kawasaki Kanagawa (JP)

(21) Appl. No.: 15/000,629

(22) Filed: Jan. 19, 2016

(30) Foreign Application Priority Data
Aug. 4, 2015 (JP) 2015-154132

(51) Int. Cl. H01L 29/06; H01L 29/40; H01L 29/78; H01L 29/423

(52) U.S. Cl. CPC H01L 29/0634; H01L 29/4236; H01L 29/407; H01L 29/7811; H01L 29/7813

(57) ABSTRACT

A semiconductor device according to an embodiment includes a first semiconductor region of a first conductivity type, a first insulating unit, a conductive unit, a stacked body, a fourth semiconductor region of a second conductivity type, a fifth semiconductor region of the first conductivity type, a gate electrode, and a gate insulating unit. The stacked body includes multiple second semiconductor regions of the first conductivity type and multiple third semiconductor regions of the second conductivity type. The multiple third semiconductor regions are connected to the conductive unit. The third semiconductor regions are provided alternately with the second semiconductor regions in a first direction from the first semiconductor region toward the portion of the first insulating unit. The gate electrode is provided on one other portion of the first insulating unit. The stacked body is positioned between the gate electrode and the conductive unit in a second direction.

### CROSS-REFERENCE TO RELATED APPLICATIONS

This application is based upon and claims the benefit of priority from Japanese Patent Application No. 2015-154132, filed on Aug. 4, 2015; the entire contents of which are incorporated herein by reference.

### FIELD

Embodiments described herein relate generally to a semiconductor device.

### BACKGROUND

There is a semiconductor device that includes a super junction structure (hereinbelow, called a SJ structure) in which n-type semiconductor regions and p-type semiconductor regions are provided alternately. In such a semiconductor device, the impurity concentration of the n-type semiconductor regions can be increased while suppressing a decrease of the breakdown voltage of the semiconductor device by reducing the widths of the n-type semiconductor regions and the widths of the p-type semiconductor regions included in the SJ structure.

### BRIEF DESCRIPTION OF THE DRAWINGS

FIG. 1 is a plan view of the semiconductor device according to the first embodiment;

FIG. 2 is an A-A′ cross-sectional view of FIG. 1;

FIGS. 3A and 3B and FIGS. 4A and 4B are cross-sectional views of processes, showing the manufacturing processes of the semiconductor device according to the first embodiment;

FIG. 5 is a cross-sectional view of a semiconductor device according to a first modification of the first embodiment;

FIG. 6 is a cross-sectional view of a semiconductor device according to a second modification of the first embodiment;

FIG. 7 is a cross-sectional view of a semiconductor device according to a third modification of the first embodiment;

FIG. 8 is a cross-sectional view of a semiconductor device according to a fourth modification of the first embodiment;

FIG. 9 is a plan view of the semiconductor device according to the second embodiment;

FIG. 10 is a partially enlarged plan view in which region B of FIG. 9 is enlarged;

FIG. 11 is a partially enlarged plan view of a semiconductor device according to a first modification of the second embodiment;

FIG. 12 is a partially enlarged plan view of a semiconductor device according to a second modification of the second embodiment;

FIG. 13 is a partially enlarged plan view of a semiconductor device according to a third modification of the second embodiment;

FIG. 14 is a partially enlarged plan view of a semiconductor device according to a fourth modification of the second embodiment;

FIG. 15 is a partially enlarged plan view of a semiconductor device according to a fifth modification of the second embodiment;

FIG. 16 is a partially enlarged plan view of a semiconductor device according to a sixth modification of the second embodiment;

FIG. 17 is a partially enlarged plan view of a semiconductor device according to a seventh modification of the second embodiment;

FIG. 18 is a partially enlarged plan view of a semiconductor device according to an eighth modification of the second embodiment;

FIG. 19 is a partially enlarged plan view of a semiconductor device according to a ninth modification of the second embodiment; and

FIG. 20 is an A-A′ cross-sectional view of FIG. 19.

### DETAILED DESCRIPTION

A semiconductor device according to an embodiment includes a first semiconductor region of a first conductivity type, a first insulating unit, a conductive unit, a stacked body, a fourth semiconductor region of a second conductivity type, a fifth semiconductor region of the first conductivity type, a gate electrode, and a gate insulating unit. The first insulating unit is provided on a portion of the first semiconductor region. The conductive unit is provided on one other portion of the first semiconductor region. The conductive unit is connected to the first semiconductor region. The stacked body includes multiple second semiconductor regions of the first conductivity type and multiple third semiconductor regions of the second conductivity type. The stacked body is provided on a portion of the first insulating unit. The multiple second semiconductor regions are connected to the conductive unit. The multiple third semiconductor regions are connected to the conductive unit. The third semiconductor regions are provided alternately with the second semiconductor regions in a first direction from the first semiconductor region toward the portion of the first insulating unit. The fourth semiconductor region is selectively provided on the stacked body. The fifth semiconductor region is selectively provided on the fourth semiconductor region. The gate electrode is provided on one other portion of the first insulating unit. The stacked body is positioned between the gate electrode and the conductive unit in a second direction perpendicular to the first direction. The gate insulating unit is provided between the gate electrode and the stacked body, between the gate electrode and the fourth semiconductor region, and between the gate electrode and the fifth semiconductor region.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described therein above are marked with like reference numerals, and a detailed description is omitted as appropriate.

An XYZ orthogonal coordinate system is used in the description of the embodiments. A direction from an n⁺-type drain region 1 toward an insulating unit 21 is taken as a Z-direction (a first direction); and two mutually-orthogonal directions perpendicular to the Z-direction are taken as an X-direction (a second direction) and a Y-direction (a third direction).

In the following description, the notations of n⁺, n, p⁺, p, and p⁻ indicate relative levels of the impurity concentrations of the conductivity types. In other words, a notation marked with “+” indicates an impurity concentration relatively higher than a notation not marked with either “+” or “−;” and a notation marked with “−” indicates an impurity concentration relatively lower than a notation not marked with either “+” or “−.”

The embodiments described below may be implemented by reversing the p-type and the n-type of the semiconductor regions.

### First Embodiment

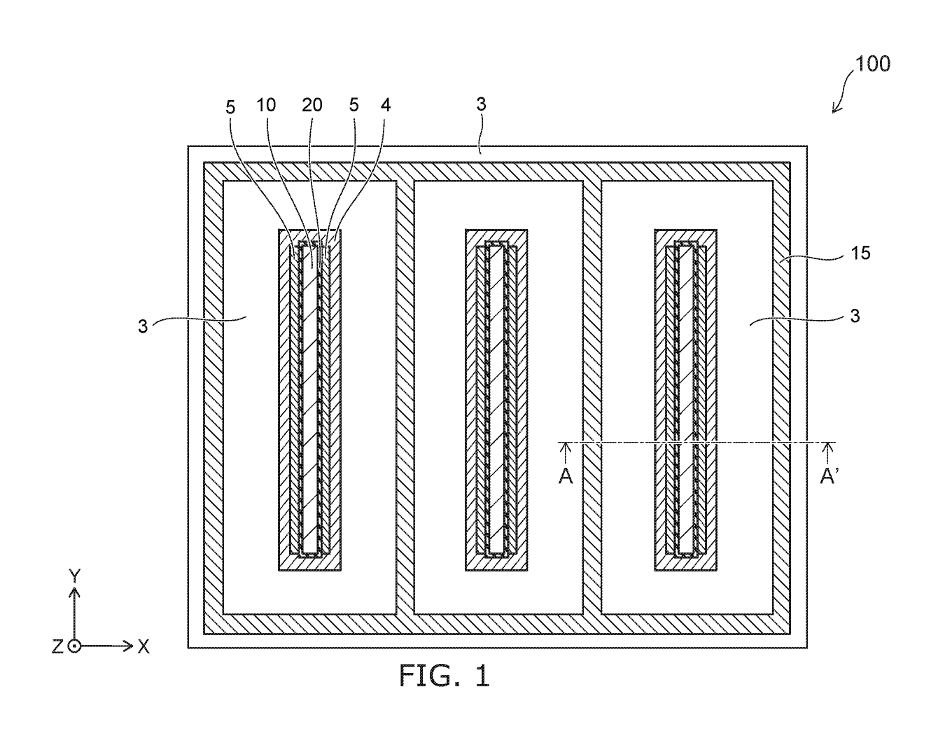

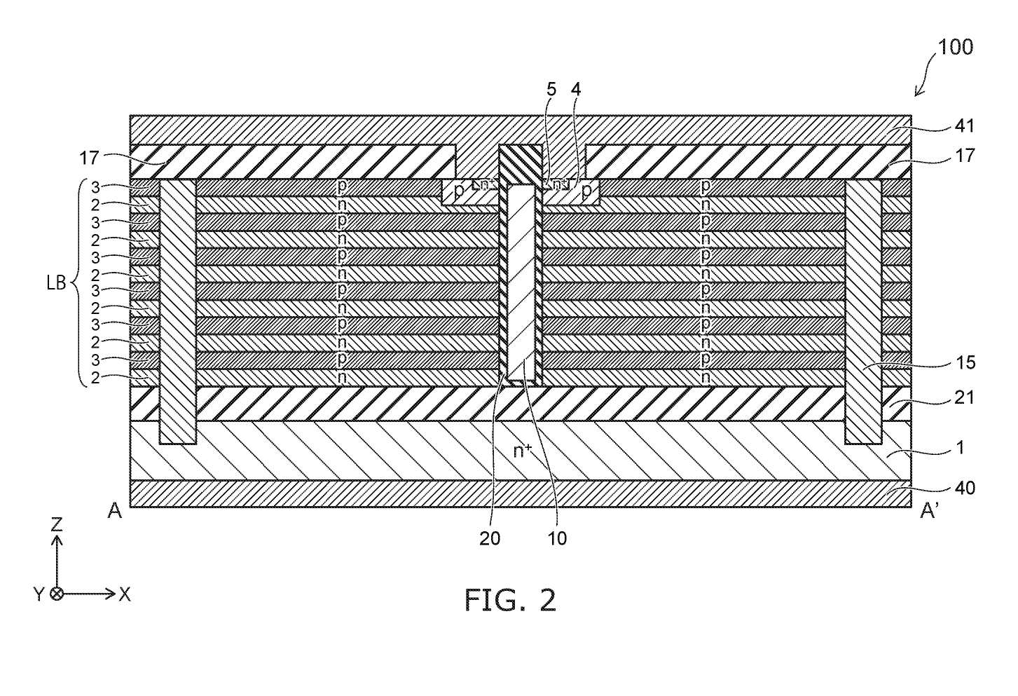

An example of a semiconductor device according to a first embodiment will now be described using FIG. 1 and FIG. 2.

FIG. 1 is a plan view of the semiconductor device 100 according to the first embodiment.

FIG. 2 is an A-A′ cross-sectional view of FIG. 1.

A source electrode 41 and an insulating layer 17 are not shown in FIG. 1.

The semiconductor device 100 is, for example, a MOSFET (Metal Oxide Semiconductor Field Effect Transistor).

As shown in FIG. 1 and FIG. 2, the semiconductor device 100 includes the drain region 1 (a first semiconductor region) of an n⁺-type (a first conductivity type), a stacked body LB, a base region 4 (a fourth semiconductor region) of a p-type (a second conductivity type), an n⁺-type source region 5 (a fifth semiconductor region), a gate electrode 10, a conductive unit 15, an insulating layer 17, a gate insulating unit 20, an insulating unit 21 (a first insulating unit), a drain electrode 40 (a second electrode), and a source electrode 41 (a third electrode).

As shown in FIG. 2, the drain electrode 40 is provided at the lower surface of the semiconductor device 100.

The n⁺-type drain region 1 is provided on the drain electrode 40 and electrically connected to the drain electrode 40.

The insulating unit 21 is provided on a portion of the n⁺-type drain region 1.

The conductive unit 15 is provided on one other portion of the n⁺-type drain region 1. The lower end of the conductive unit 15 is surrounded with the n⁺-type drain region 1 along the X-Y plane. The conductive unit 15 is electrically connected to the n⁺-type drain region 1. A portion of the conductive unit 15 is surrounded with the insulating unit 21 along the X-Y plane.

The stacked body LB and the gate electrode 10 are provided on the insulating unit 21. The stacked body LB is positioned between the gate electrode 10 and the conductive unit 15. The gate insulating unit 20 is provided between the gate electrode 10 and the stacked body LB. N-type semiconductor regions 2 and p-type semiconductor regions 3 contact the gate insulating unit 20.

The stacked body LB includes the multiple n-type semiconductor regions 2 (second semiconductor regions) and the multiple p-type semiconductor regions 3 (third semiconductor regions). The n-type semiconductor regions 2 and the p-type semiconductor regions 3 are provided alternately in the Z-direction.

The conductive unit 15 is connected to the multiple n-type semiconductor regions 2 and the multiple p-type semiconductor regions 3.

In the example shown in FIG. 2, the n-type semiconductor region 2 is positioned at the lower end of the stacked body LB; and the p-type semiconductor region 3 is positioned at the upper end of the stacked body LB. However, one of the n-type semiconductor region 2 or the p-type semiconductor region 3 may be positioned at the upper end and lower end of the stacked body LB.

The p-type base region 4 is selectively provided on the stacked body LB.

The n⁺-type source region 5 is selectively provided on the p-type base region 4.

The p-type base region 4 and the n⁺-type source region 5 contact the gate insulating unit 20 and oppose, with the gate insulating unit 20 interposed, the gate electrode 10.

At least one of the multiple p-type semiconductor regions 3 is separated from the p-type base region 4 in the Z-direction. For example, in the semiconductor device 100 shown in FIG. 2, the multiple p-type semiconductor regions 3 other than the p-type semiconductor region 3 positioned at the upper end of the stacked body LB are separated from the p-type base region 4 in the Z-direction.

The insulating layer 17 is provided on the stacked body LB and on the conductive unit 15.

The source electrode 41 is provided at the upper surface of the semiconductor device 100 and is positioned on the p-type base region 4, the n⁺-type source region 5, and the insulating layer 17. The n⁺-type source region 5 and at least a portion of the p-type base region 4 are not covered with the insulating layer 17; and these semiconductor regions are electrically connected to the source electrode 41.

A portion of the gate insulating unit 20 is provided between the source electrode 41 and the gate electrode 10; and these electrodes are electrically isolated.

As shown in FIG. 1, the gate electrode 10 is surrounded with the p-type base region 4 and provided between the n⁺-type source regions 5 in the X-direction. The gate electrode 10, the p-type base region 4, and the n⁺-type source region 5 are surrounded with the conductive unit 15 and the stacked body LB along the X-Y plane.

A portion of the stacked body LB contacts the gate insulating unit 20 and is surrounded with the conductive unit 15. One other portion of the stacked body LB that does not contact the gate insulating unit 20 is provided around the conductive unit 15.

The gate electrode 10, the p-type base region 4, and the n⁺-type source region 5 are multiply provided in the X-direction; and each extend in the Y-direction.

The MOSFET is switched to the ON state by applying a voltage not less than the threshold to the gate electrode 10 in the state in which a voltage that is positive with respect to the source electrode 41 is applied to the drain electrode 40. At this time, a channel (an inversion layer) is formed at the gate insulating unit 20 vicinity in the p-type semiconductor regions 3 and the p-type base region 4. The electrons that are injected via the n⁺-type source region 5 flow through each of the n-type semiconductor regions 2 via the channel and are discharged from the drain electrode 40 via the conductive unit 15 and the n⁺-type drain region 1.

Depletion layers spread from the p-n junction surfaces between the n-type semiconductor regions 2 and the p-type semiconductor regions 3 toward each of the semiconductor regions when the MOSFET is in the OFF state and a potential that is positive with respect to the potential of the source electrode 41 is applied to the drain electrode 40. The breakdown voltage of the semiconductor device can be increased by the depletion layers spreading from the p-n junction surfaces between the n-type semiconductor regions 2 and the p-type semiconductor regions 3 in the OFF state. Also, it is possible to increase the impurity concentration of each of the semiconductor regions according to the increase of the breakdown voltage.

Examples of the materials of the components will now be described.

The n⁺-type drain region 1, the n-type semiconductor region 2, the p-type semiconductor region 3, the p-type base region 4, and the n⁺-type source region 5 include silicon, silicon carbide, gallium nitride, or gallium arsenide as a semiconductor material.

Arsenic, phosphorus, or antimony may be used as an n-type impurity added to the semiconductor material. Boron may be used as a p-type impurity.

The gate electrode 10 and the conductive unit 15 include a conductive material such as polysilicon, etc.

The gate insulating unit 20, the insulating unit 21, and the insulating layer 17 include an insulating material such as silicon oxide, etc.

The drain electrode 40 and the source electrode 41 include a metal material such as aluminum, etc.

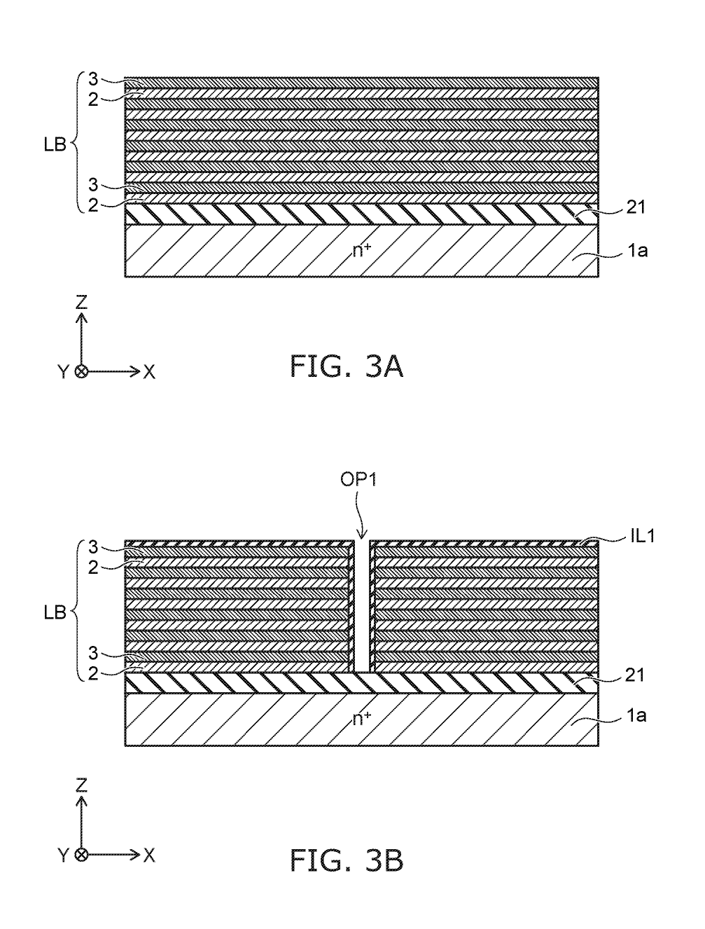

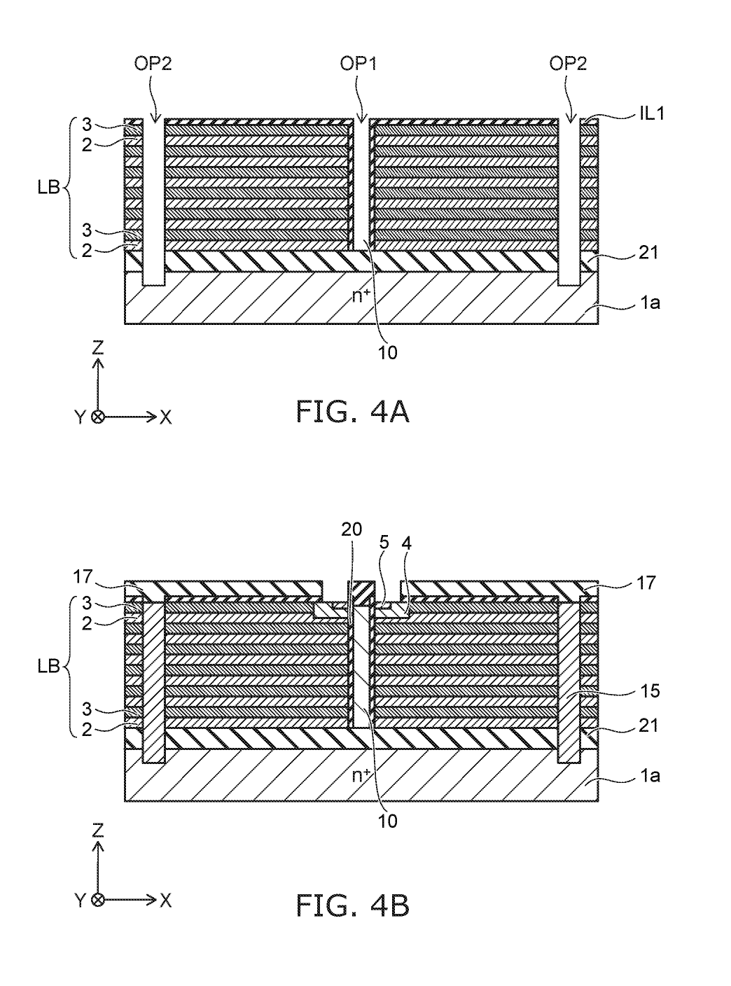

An example of the method for manufacturing the semiconductor device according to the first embodiment will now be described using FIGS. 3A and 3B and FIGS. 4A and 4B.

FIGS. 3A and 3B and FIGS. 4A and 4B are cross-sectional views of processes, showing the manufacturing processes of the semiconductor device 100 according to the first embodiment.

First, an n⁺-type semiconductor layer 1a is prepared. Then, the insulating unit 21 is formed on the n⁺-type semiconductor layer 1a. Continuing, the n-type semiconductor region 2 is formed on the insulating unit 21 by bonding. Subsequently, the n-type semiconductor region 2 and the p-type semiconductor region 3 are epitaxially grown alternately on the n-type semiconductor region 2; and the stacked body LB is formed as shown in FIG. 3A.

Then, an opening OP1 that pierces the stacked body LB is made. The opening OP1 is made to correspond to the position where the gate electrode 10 is to be provided. At this time, for example, a portion of the upper surface of the insulating unit 21 is exposed via the opening OP1. Continuing, an insulating layer IL1 is formed on the inner wall of the opening OP1 and the upper surface of the stacked body LB as shown in FIG. 3B by thermal oxidation of the stacked body LB.

Continuing as shown in FIG. 4A, an opening OP2 that pierces the insulating layer ILL the stacked body LB, and the insulating unit 21 and reaches the n⁺-type semiconductor layer 1a is made. The opening OP2 is made to correspond to the position where the conductive unit 15 is to be provided. Continuing, a conductive layer is formed on the stacked body LB to fill the openings OP1 and OP2. By causing the upper surface of the conductive layer to recede, the gate electrode 10 is formed in the interior of the opening OP1; and the conductive unit 15 is formed in the interior of the opening OP2.

Then, the p-type base region 4 and the n⁺-type source region 5 are formed in the upper portion of the stacked body LB by selectively performing ion implantation of a p-type impurity and an n-type impurity sequentially. Continuing, an insulating layer that covers the gate electrode 10 and the conductive unit 15 is formed. The insulating layer and the insulating layer IL1 are patterned so that the p-type base region 4 and the n⁺-type source region 5 are exposed. The gate insulating unit 20 and the insulating layer 17 are formed by this process. The state at this time is shown in FIG. 4B.

Then, a metal layer that covers the p-type base region 4 and the n⁺-type source region 5 is formed; and the source electrode 41 is formed by patterning the metal layer. Continuing, the back surface of the n⁺-type semiconductor layer 1a is polished until the n⁺-type semiconductor layer 1a has a prescribed thickness. The drain electrode 40 is formed by forming a metal layer on the polished back surface of the n⁺-type semiconductor layer 1a.

The semiconductor device 100 shown in FIG. 1 and FIG. 2 is obtained by the processes described above.

Operations and effects according to the embodiment will now be described.

First, a case will be described as a reference example where the n-type semiconductor regions and the p-type semiconductor regions are provided alternately in the X-direction or the Y-direction. In such a case, for example, the Si structure is formed by forming a semiconductor layer of the n-type; subsequently making multiple openings; and filling a p-type semiconductor layer into the openings.

However, in this method, to reduce the widths (the lengths in a direction perpendicular to the p-n junction surface) of the semiconductor regions included in the Si structure, it is necessary to increase the aspect ratio of the openings that are made and reduce the spacing between the openings. Therefore, it is not easy to reduce the widths of the semiconductor regions.

Conversely, in the semiconductor device according to the embodiment, the n-type semiconductor region 2 and the p-type semiconductor region 3 are provided alternately in the Z-direction. In the case where such a configuration is employed, it is possible to reduce the widths of the semiconductor regions by reducing the thickness when forming each semiconductor region.

In other words, according to the embodiment, a semiconductor device can be provided in which it is possible to easily reduce the width of each of the semiconductor regions included in the Si structure.

In the embodiment, at least one of the multiple p-type semiconductor regions 3 is provided to be separated from the p-type base region 4 in the Z-direction. By the p-type semiconductor region 3 and the p-type base region 4 being provided to be separated, the potential of the p-type semiconductor region 3 is not easily affected by the potential of the p-type base region 4. Therefore, spreading of the depletion layer from the p-n junction surface between the n-type semiconductor region 2 and the p-type semiconductor region 3 caused by the voltage between the source-drain can be suppressed. By suppressing the spreading of the depletion layer due to the source-drain voltage, the confinement of the current path in the n-type semiconductor region 2 in the ON state can be suppressed even in the case where the width of the n-type semiconductor region 2 and the width of the p-type semiconductor region 3 are narrow. By suppressing the confinement of the current path in the n-type semiconductor region 2, the decrease of the current value that can be caused to flow in the semiconductor device can be suppressed.

In other words, according to the embodiment, by providing at least one of the multiple p-type semiconductor regions 3 to be separated from the p-type base region 4, the decrease of the maximum current value of the semiconductor device that occurs in the case where the width of the n-type semiconductor region 2 and the width of the p-type semiconductor region 3 are reduced can be suppressed.

In the embodiment, because the n-type semiconductor region 2 and the p-type semiconductor region 3 are provided alternately in the Z-direction, it is possible to increase the current path by increasing the number of stacks of these semiconductor regions.

In other words, according to the embodiment, it is easy to increase the maximum current value of the semiconductor device while suppressing the increase of the surface area of the semiconductor device.

In the embodiment, the conductive unit 15 that is electrically connected to the n⁺-type drain region 1 is provided to surround a portion of the stacked body LB and each of the gate electrodes 10. By employing such a structure, it is possible to enlarge the operation region as a semiconductor device and reduce the ON resistance.

In the embodiment, the p-type base region 4 is provided around the gate electrode 10 along the X-Y plane. By employing such a structure, it is possible to suppress the electric field concentration at the upper end of the gate electrode 10 at the end portion in the X-direction and the end portion in the Y-direction and suppress the breakdown of the gate insulating unit 20.

### First Modification

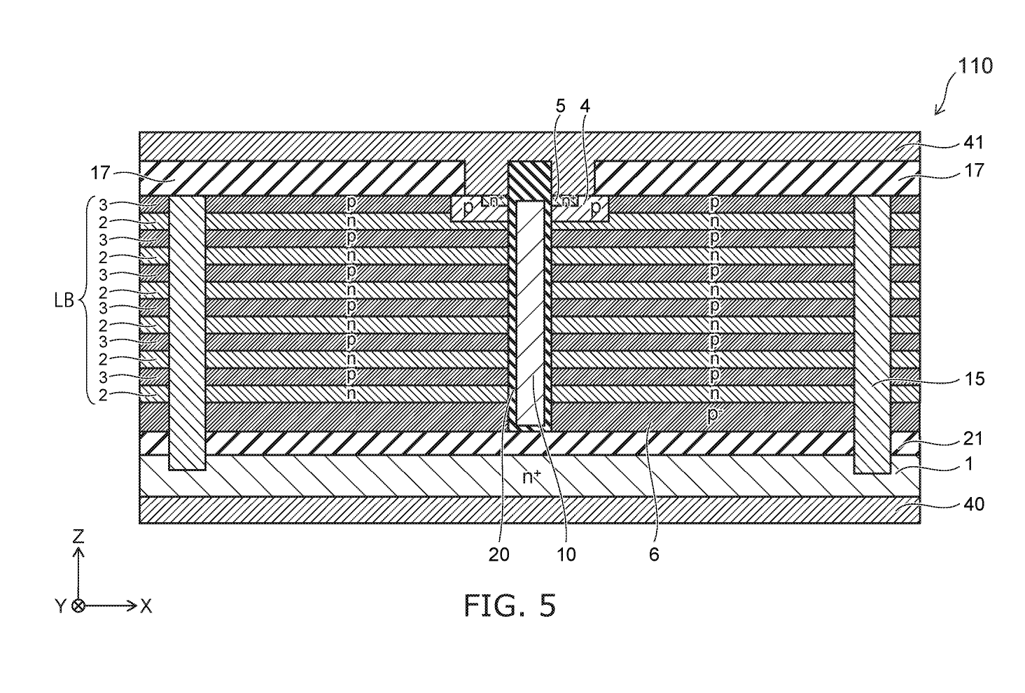

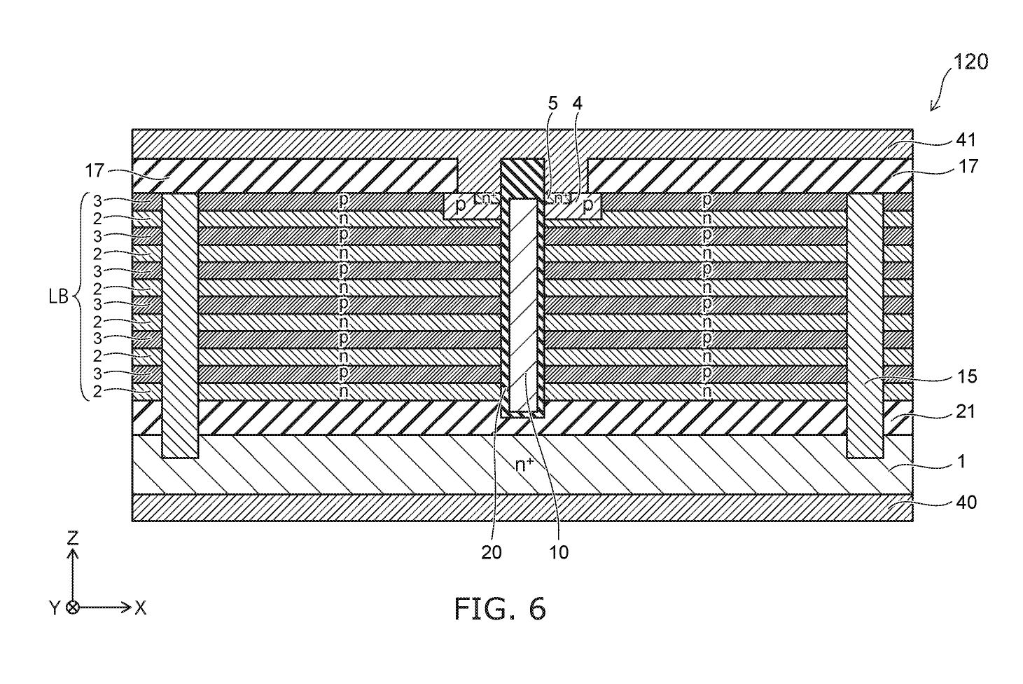

FIG. 5 is a cross-sectional view of a semiconductor device 110 according to a first modification of the first embodiment.

The semiconductor device 110 differs from the semiconductor device 100 in that a p⁻-type semiconductor region 6 (a sixth semiconductor region) is further included.

The p⁻-type semiconductor region 6 is provided between the insulating unit 21 and the stacked body LB in the Z-direction. The p⁻-type semiconductor region 6 surrounds a portion of the gate electrode 10 and a portion of the conductive unit 15 along the X-Y plane.

By providing the p⁻-type semiconductor region 6 between the insulating unit 21 and the stacked body LB, compared to the semiconductor device 100, it is possible to reduce the electric field strength at the lower end of the gate electrode 10 and increase the breakdown voltage of the semiconductor device.

### Third Modification

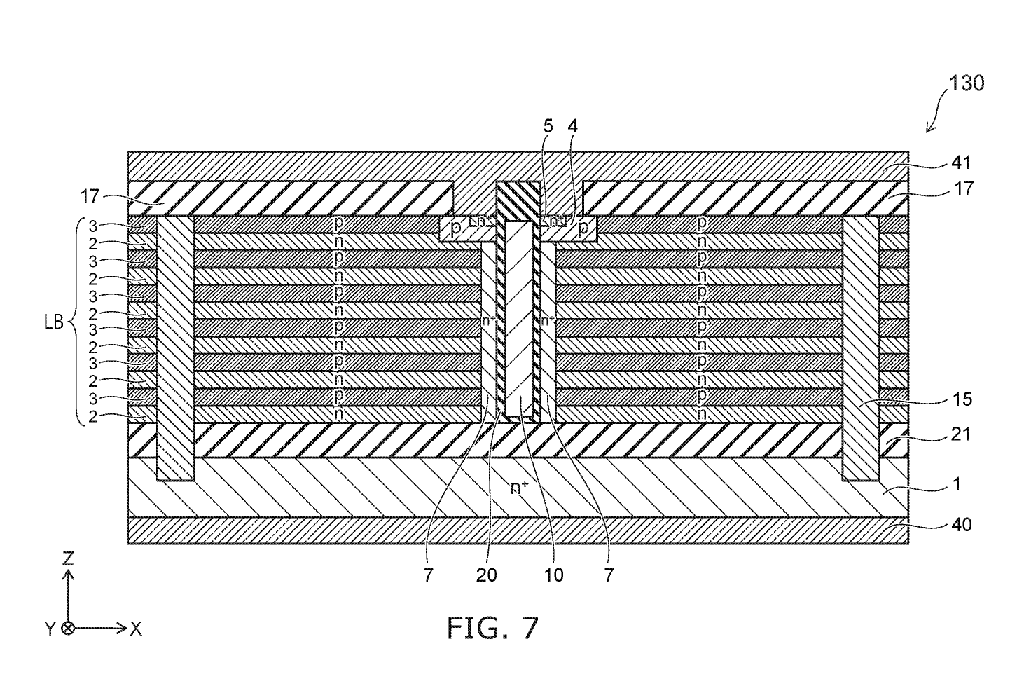

FIG. 7 is a cross-sectional view of a semiconductor device 130 according to a third modification of the first embodiment.

The semiconductor device 130 differs from the semiconductor device 100 in that an n⁺-type semiconductor region 7 (a seventh semiconductor region) is further included.

The n⁺-type semiconductor region 7 is provided between the gate insulating unit 20 and the stacked body LB in the X-direction. The n⁺-type semiconductor region 7 contacts the gate insulating unit 20 and is connected to the multiple n-type semiconductor regions 2. The n⁺-type semiconductor region 7 is positioned between the insulating unit 21 and the n⁺-type source region 5 in the Z-direction.

In the ON state of the semiconductor device 100, the n-type semiconductor regions 2 and the n⁺-type source region 5 are connected via the channel formed in the p-type semiconductor regions 3 and the p-type base region 4. Conversely, in the ON state of the semiconductor device 130, the n-type semiconductor regions 2 and the n⁺-type source region 5 are connected via the n⁺-type semiconductor region 7 and the channel formed in the p-type base region 4.

The electrical resistance of the n⁺-type semiconductor region 7 for electrons is lower than the electrical resistance for electrons of the channel formed in the p-type semiconductor regions 3. Also, in the ON state, a storage layer of the electrons is formed in the n⁺-type semiconductor region 7. Therefore, in the ON state, the electrical resistance of the n⁺-type semiconductor region 7 for electrons is reduced even further.

Therefore, according to the modification, compared to the semiconductor device 100, the electrical resistance for electrons between the n⁺-type source region 5 and each of the n-type semiconductor regions 2 can be reduced; and it is possible to reduce the ON resistance of the semiconductor device.

### Fourth Modification

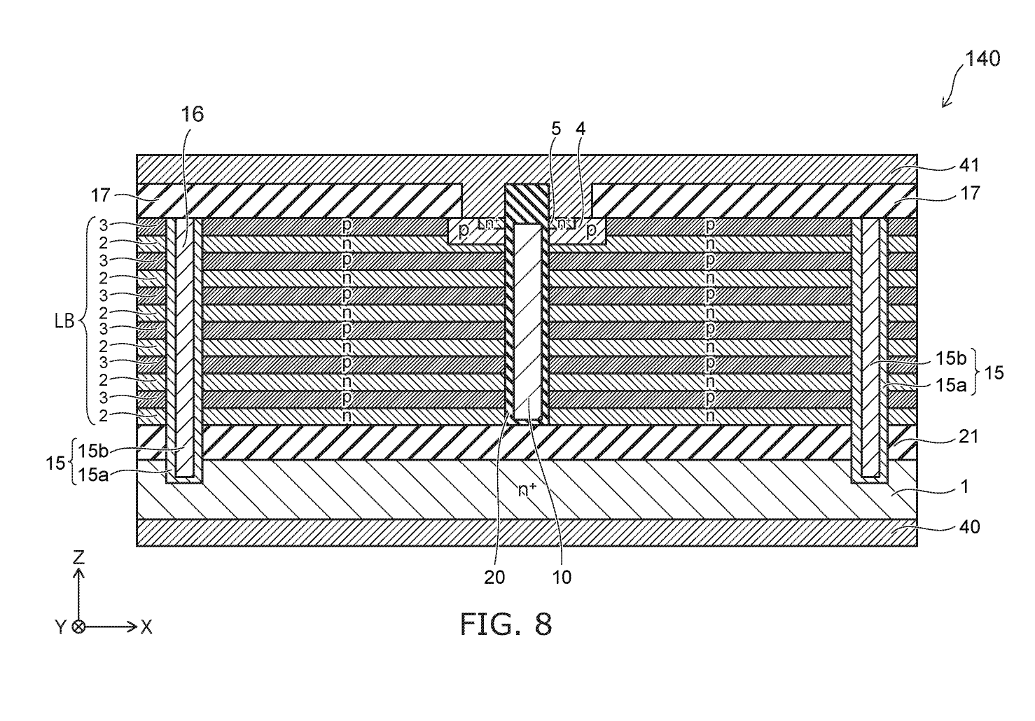

FIG. 8 is a cross-sectional view of a semiconductor device 140 according to a fourth modification of the first embodiment.

The structure of the conductive unit 15 of the semiconductor device 140 is different from that of the semiconductor device 100.

In the semiconductor device 140, the conductive unit 15 includes a first conductive portion 15a and a second conductive portion 15b.

The second conductive portion 15b is surrounded with the first conductive portion 15a. More specifically, the first conductive portion 15a is provided between the second conductive portion 15b and the n⁺-type drain region 1, between the second conductive portion 15b and the insulating unit 21, and between the second conductive portion 15b and the stacked body LB.

The first conductive portion 15a includes polycrystalline silicon.

The second conductive portion 15b includes a metal. The second conductive portion 15b includes, for example, at least one metal of aluminum, titanium, nickel, tungsten, copper, or gold. The second conductive portion 15b may further include a metal compound such as titanium nitride, etc.

The electrical resistance of the second conductive portion 15b is lower than the electrical resistance of the first conductive portion 15a including polycrystalline silicon. Therefore, by the conductive unit 15 including the second conductive portion 15b, it is possible to reduce even further the ON resistance of the semiconductor device.

It is possible to implement the modifications according to the first embodiment described above in combination with each other.

### Second Embodiment

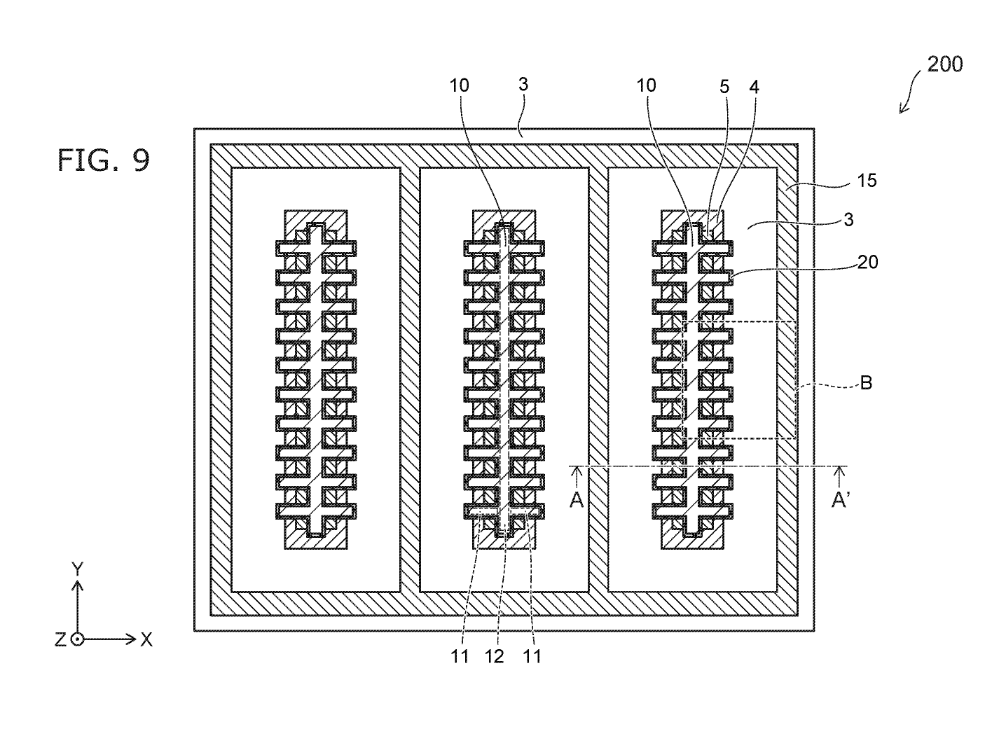

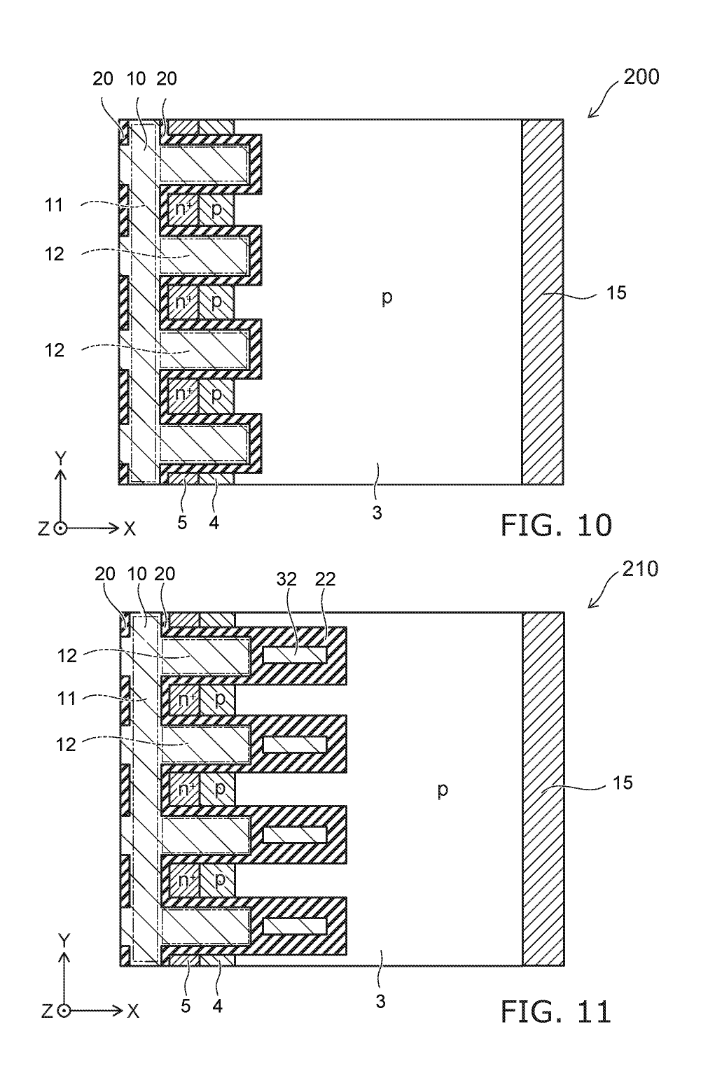

An example of a semiconductor device according to a second embodiment will now be described using FIG. 9 and FIG. 10.

FIG. 9 is a plan view of the semiconductor device 200 according to the second embodiment.

FIG. 10 is a partially enlarged plan view in which region B of FIG. 9 is enlarged.

The source electrode 41 and the insulating layer 17 are not shown in FIG. 9 and FIG. 10. The A-A′ cross-sectional view of FIG. 9 is similar to, for example, the cross-sectional view of the semiconductor device 100 shown in FIG. 2.

As shown in FIG. 9 and FIG. 10, the structure of the gate electrode 10 of the semiconductor device 200 is different from that of the semiconductor device 100.

The gate electrode 10 includes a first electrode portion 11 and a second electrode portion 12.

The first electrode portion 11 extends in the Y-direction.

The second electrode portion 12 is multiply provided in the X-direction and the Y-direction; and each of the second electrode portions 12 extends in the X-direction.

The first electrode portion 11 contacts the multiple second electrode portions 12 in the Y-direction and is positioned between the second electrode portions 12 in the X-direction.

The n⁺-type source region 5, the p-type base region 4, and a portion of the stacked body LB are provided between the second electrode portions 12 in the Y-direction. The first electrode portion 11 and the second electrode portions 12 extend in the Z-direction and oppose, with the gate insulating unit 20 interposed, the multiple n-type semiconductor regions 2 and the multiple p-type semiconductor regions 3.

By the gate electrode 10 including the second electrode portions 12, the surface area of the gate electrode 10 opposing the stacked body LB and the p-type base region 4 can be increased. By increasing the surface area of the gate electrode 10 opposing the stacked body LB and the p-type base region 4, the surface area of the channel formed in the p-type semiconductor regions 3 and the p-type base region 4 in the ON state can be increased. Therefore, according to the embodiment, compared to the semiconductor device 100, it is possible to reduce the ON resistance of the semiconductor device.

### First Modification

FIG. 11 is a partially enlarged plan view of a semiconductor device 210 according to a first modification of the second embodiment.

The source electrode 41 and the insulating layer 17 are not shown in FIG. 11.

The semiconductor device 210 differs from the semiconductor device 200 in that an electrode 32 (a first electrode) and an insulating unit 22 (a second insulating unit) are further included.

The electrode 32 is provided between the second electrode portion 12 and the conductive unit 15 in the X-direction. Similarly to the gate electrode 10, the electrode 32 extends in the Z-direction and opposes, with the insulating unit 22 interposed, the multiple n-type semiconductor regions 2 and the multiple p-type semiconductor regions 3. The length in the Y-direction of the electrode 32 is shorter than the length in the Y-direction of the second electrode portion 12. The electrode 32 is electrically connected to the source electrode 41.

By providing the electrode 32, a depletion layer spreads toward the n-type semiconductor regions 2 from the interface between the stacked body LB and the insulating unit 22 when the semiconductor device is switched from the ON state to the OFF state. Therefore, it is possible to suppress the decrease of the breakdown voltage even in the case where the ON resistance of the semiconductor device is reduced by increasing the n-type impurity concentration of the n-type semiconductor regions 2.

By providing the electrode 32 between the gate electrode 10 and the conductive unit 15, the electrostatic capacitance between the gate electrode 10 and the conductive unit 15 can be reduced. Therefore, the time that is necessary for switching the semiconductor device can be shortened.

### Second Modification

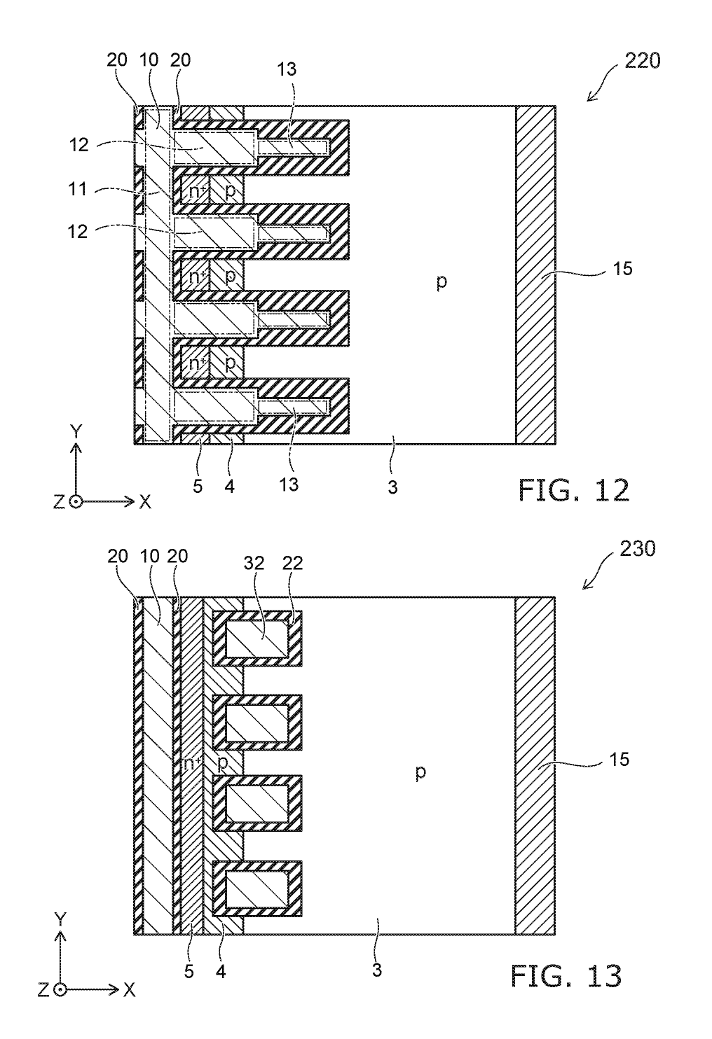

FIG. 12 is a partially enlarged plan view of a semiconductor device 220 according to a second modification of the second embodiment.

The source electrode 41 and the insulating layer 17 are not shown in FIG. 12.

The semiconductor device 220 differs from the semiconductor device 200 in that the gate electrode 10 further includes a third electrode portion 13.

The third electrode portion 13 is multiply provided in the Y-direction; and each of the third electrode portions 13 extends in the X-direction. The third electrode portion 13 is positioned between the second electrode portion 12 and the conductive unit 15 in the X-direction. Similarly to the first electrode portion 11 and the second electrode portion 12, the third electrode portion 13 extends in the Z-direction and opposes, with the gate insulating unit 20 interposed, the multiple n-type semiconductor regions 2 and the multiple p-type semiconductor regions 3. The length in the Y-direction of the third electrode portion 13 is shorter than the length in the Y-direction of the second electrode portion 12.

By providing the third electrode portion 13, the surface area of the gate electrode 10 opposing the stacked body LB can be increased. By increasing the surface area of the gate electrode 10 opposing the stacked body LB, the surface area of the channel formed in the p-type semiconductor regions 3 and the p-type base region 4 in the ON state can be increased. Therefore, according to the modification, compared to the semiconductor device 200, it is possible to further reduce the ON resistance of the semiconductor device.

### Third Modification

FIG. 13 is a partially enlarged plan view of a semiconductor device 230 according to a third modification of the second embodiment.

The source electrode 41 and the insulating layer 17 are not shown in FIG. 13.

The semiconductor device 230 differs from the semiconductor device 100 in that the electrode 32 and the insulating unit 22 are further included.

The electrode 32 is provided between the gate electrode 10 and the conductive unit 15 in the X-direction. The electrode 32 is multiply provided in the Y-direction. Similarly to the gate electrode 10, the electrode 32 extends in the Z-direction and opposes the stacked body LB with the insulating unit 22 interposed. At least a portion of the insulating unit 22 contacts the p-type base region 4.

The electrode 32 is electrically isolated from the gate electrode 10, the drain electrode 40, and the source electrode 41. The electrode 32 is connected to a power supply that is different from that of the gate electrode 10 and functions as a second gate electrode.

As described above, depletion layers spread toward each of the semiconductor regions from the p-n junction surfaces between the n-type semiconductor regions 2 and the p-type semiconductor regions 3 in the OFF state. When turned ON, the depletion layers disappear due to the holes and the electrons injected into these semiconductor regions.

However, in the case where the p-type semiconductor regions 3 are provided to be separated from the p-type base region 4, time is necessary to inject the holes into the p-type semiconductor regions 3 when turned ON. In the case where time is necessary to inject the holes into the p-type semiconductor regions 3, time is necessary also for the depletion layers in the p-type semiconductor regions 3 to disappear. In the case where the depletion layers exist in the p-type semiconductor regions 3, the depletion layers spread also in the n-type semiconductor regions 2; and therefore, the ON resistance undesirably increases transitionally when turned ON.

Conversely, according to the modification when turned ON by applying a voltage not less than the threshold to the gate electrode 10, the holes can be supplied to each of the p-type semiconductor regions 3 from the p-type base region 4 by applying a negative voltage to the electrode 32 to form channels for the holes in the n-type semiconductor regions 2.

Therefore, according to the modification, it is possible to suppress the transitional increase of the ON resistance due to the p-type semiconductor regions 3 being provided to be separated from the p-type base region 4.

When the semiconductor device is turned OFF, the resistance when the holes are discharged toward the source electrode 41 from the interior of the semiconductor device can be reduced by applying a negative voltage to the electrode 32 to form channels for the holes in the n-type semiconductor regions 2. By reducing the resistance for the holes, it is possible to reduce the voltage drop due to the movement of the holes and suppress a parasitic bipolar transistor operation.

By providing the electrode 32 between the gate electrode 10 and the conductive unit 15, the electrostatic capacitance between the gate electrode 10 and the conductive unit 15 can be reduced. Therefore, it is possible to shorten the time necessary for switching the semiconductor device.

### Fourth Modification

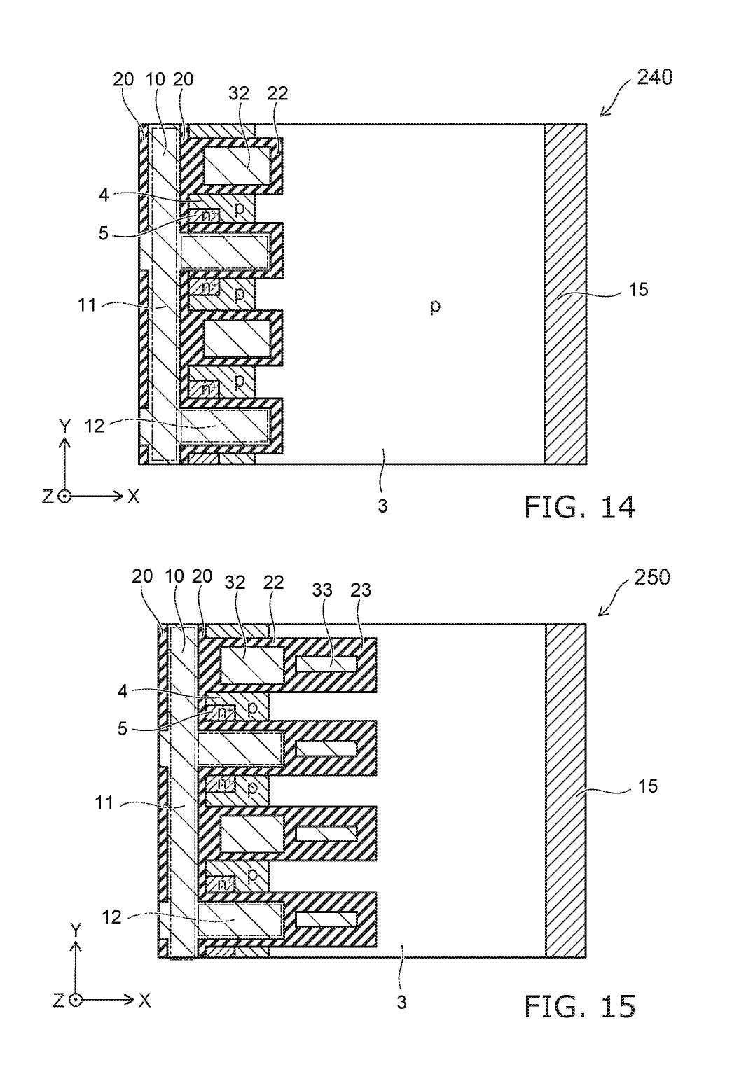

FIG. 14 is a partially enlarged plan view of a semiconductor device 240 according to a fourth modification of the second embodiment.

The source electrode 41 and the insulating layer 17 are not shown in FIG. 14.

The semiconductor device 240 differs from the semiconductor device 200 in that the electrode 32 and the insulating unit 22 are further included.

Similarly to the third modification, the electrode 32 functions as the second gate electrode. The electrode 32 is multiply provided in the Y-direction. The second electrode portions 12 and the electrodes 32 are provided alternately in the Y-direction.

The n⁺-type source region 5 is selectively provided on the second electrode portion 12 side between the second electrode portion 12 and the electrode 32. In other words, a portion of the p-type base region 4 is provided between the n⁺-type source region 5 and the electrode 32 in the Y-direction.

By the electrode 32 being provided and by the gate electrode 10 including the second electrode portion 12, the parasitic bipolar transistor operation can be suppressed while reducing the ON resistance of the semiconductor device.

By alternately providing the second electrode portions 12 and the electrodes 32 in the Y-direction, the current density that flows between the second electrode portion 12 and the electrode 32 is reduced; and it is possible to suppress even further the latch up of the parasitic bipolar transistor.

### Fifth Modification

FIG. 15 is a partially enlarged plan view of a semiconductor device 250 according to a fifth modification of the second embodiment.

The source electrode 41 and the insulating layer 17 are not shown in FIG. 15.

The semiconductor device 250 differs from the semiconductor device 240 in that an electrode 33 and an insulating unit 23 are further included.

The electrode 33 is multiply provided in the Y-direction. In the X-direction, each of the electrodes 33 is provided between the electrode 32 and the conductive unit 15 or between the second electrode portion 12 and the conductive unit 15. Similarly to the gate electrode 10 and the electrode 32, the electrode 33 extends in the Z-direction and opposes, with the insulating unit 23 interposed, the stacked body LB.

The electrode 33 is electrically connected to the source electrode 41. The length in the Y-direction of the electrode 33 is shorter than the length in the Y-direction of the second electrode portion 12 and shorter than the length in the Y-direction of the electrode 32.

By providing the electrode 33, compared to the semiconductor device 240, it is possible to suppress the decrease of the breakdown voltage even in the case where the ON resistance of the semiconductor device is reduced by increasing the n-type impurity concentration of the n-type semiconductor regions 2. By providing the electrode 33 between the gate electrode 10 and the conductive unit 15, it is possible to reduce the electrostatic capacitance between the gate electrode 10 and the conductive unit 15.

### Sixth Modification

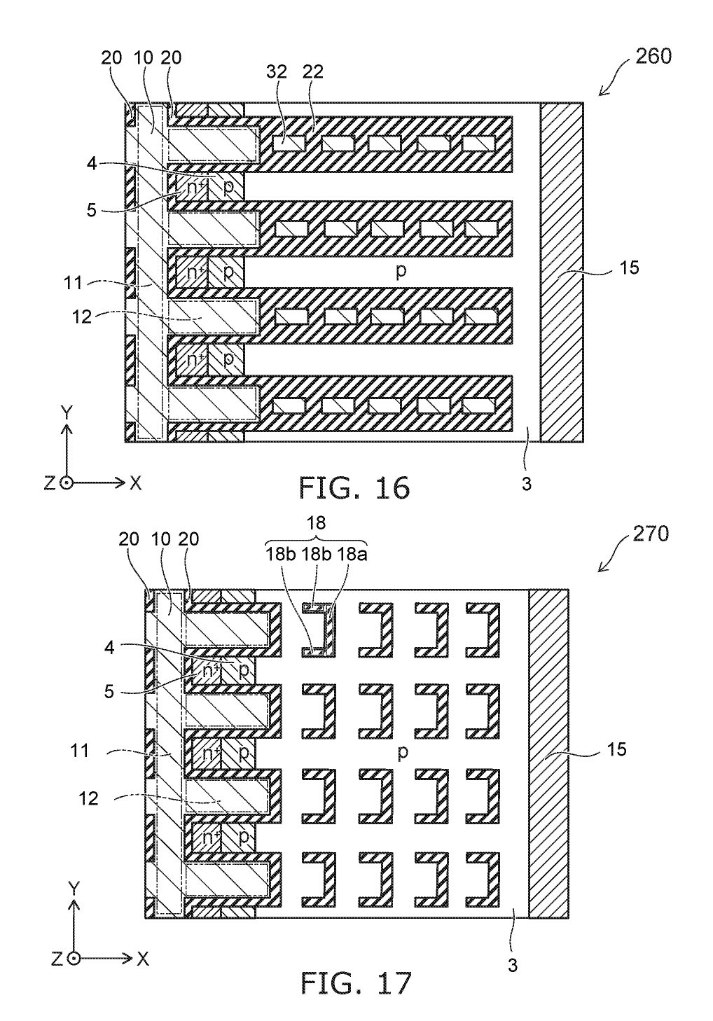

FIG. 16 is a partially enlarged plan view of a semiconductor device 260 according to a sixth modification of the second embodiment.

The source electrode 41 and the insulating layer 17 are not shown in FIG. 16.

The semiconductor device 260 differs from the semiconductor device 210 in that the electrode 32 and the insulating unit 22 are further included.

The electrode 32 is multiply provided in the X-direction and the Y-direction. The multiple electrodes 32 are arranged in the X-direction between the conductive unit 15 and each of the second electrode portions 12. The multiple electrodes 32 that are arranged in the X-direction are surrounded with the insulating unit 22. Similarly to the gate electrode 10, the electrode 32 extends in the Z-direction and opposes, with the insulating unit 22 interposed, the stacked body LB.

Each of the electrodes 32 is electrically isolated from the other electrodes and the other conductive units. Also, the electrodes 32 are electrically isolated from each other; and the potentials of the electrodes 32 are floating.

The potential at each point in the interior of the stacked body LB is affected by the difference between the n-type impurity concentration of the n-type semiconductor regions 2 and the p-type impurity concentration of the p-type semiconductor regions 3. As the concentration difference increases, the change of the electric field strength in the stacked body LB increases; and the breakdown voltage of the semiconductor device decreases.

Conversely, in the modification, the multiple electrodes 32 that have floating potentials are arranged between the conductive unit 15 and the second electrode portions 12. The potential of each of the electrodes 32 is determined by the capacitive coupling between the mutually-adjacent electrodes. Therefore, the potential of each of the electrodes 32 is determined according to the position of the electrode 32. Accordingly, even in the case where a difference exists between the n-type impurity concentration of the n-type semiconductor regions 2 and the p-type impurity concentration of the p-type semiconductor regions 3, it is possible to suppress the change of the electric field strength and suppress the decrease of the breakdown voltage of the semiconductor device.

### Seventh Modification

FIG. 17 is a partially enlarged plan view of a semiconductor device 270 according to a seventh modification of the second embodiment.

The source electrode 41 and the insulating layer 17 are not shown in FIG. 17.

The semiconductor device 270 differs from the semiconductor device 200 in that an insulating unit 18 (a third insulating unit) is further included.

The insulating unit 18 is multiply provided in the X-direction and the Y-direction. In the example shown in FIG. 17, the multiple insulating units 18 are arranged in the X-direction with each of the second electrode portions 12. However, the insulating units 18 may not be arranged with the second electrode portion 12 in the X-direction. The insulating unit 18 extends in the Z-direction and reaches the insulating unit 21.

The insulating unit 18 includes a first insulating portion 18a and a second insulating portion 18b. The first insulating portion 18a extends in the Y-direction. The second insulating portion 18b is multiply provided in the Y-direction; and each of the second insulating portions 18b extends in the X-direction. The second insulating portions 18b are positioned between the first insulating portion 18a and the gate electrode 10 in the X-direction.

In the case where the insulating units 18 are provided, electrons are stored in the region between the second insulating portions 18b in the OFF state of the semiconductor device. In other words, the potential in this region is affected by the stored amount of the electrons. The stored amount of the electrons is dependent on the size and configuration of the insulating unit 18. Therefore, even in the case where a difference exists between the n-type impurity concentration of the n-type semiconductor regions 2 and the p-type impurity concentration of the p-type semiconductor regions 3, it is possible to suppress the fluctuation of the electric field strength due to the concentration difference and suppress the breakdown voltage decrease of the semiconductor device.

### Eighth Modification

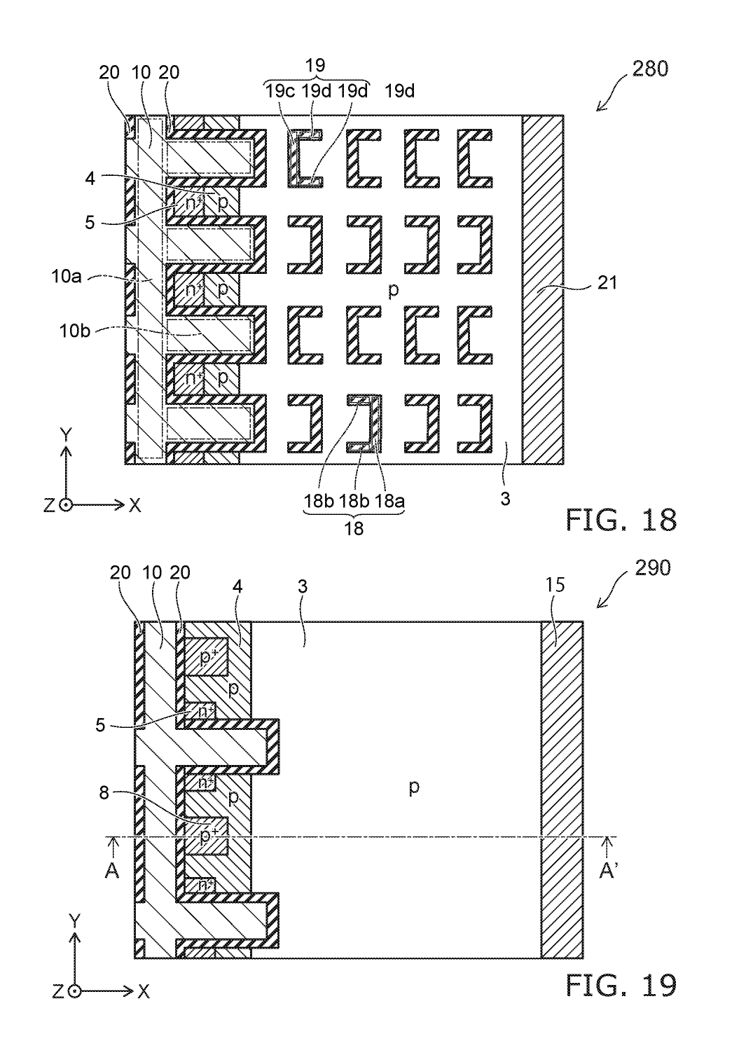

FIG. 18 is a partially enlarged plan view of a semiconductor device 280 according to an eighth modification of the second embodiment.

The source electrode 41 and the insulating layer 17 are not shown in FIG. 18.

The semiconductor device 280 differs from the semiconductor device 200 in that the insulating unit 18 and an insulating unit 19 (a fourth insulating unit) are further included.

The insulating unit 18 is multiply provided in the X-direction and the Y-direction. Similarly, the insulating unit 19 is multiply provided in the X-direction and the Y-direction.

The multiple insulating units 18 or the multiple insulating units 19 are arranged in the X-direction between the conductive unit 15 and each of the second electrode portions 12.

In the example shown in FIG. 18, the insulating units 18 and the insulating units 19 are provided alternately in the Y-direction. However, the example is not limited thereto; and the multiple insulating units 18 and the multiple insulating units 19 may be provided alternately in the Y-direction.

The insulating unit 19 includes a third insulating portion 19c and a fourth insulating portion 19d.

The third insulating portion 19c extends in the Y-direction. The fourth insulating portion 19d is multiply provided in the Y-direction; and each of the fourth insulating portions 19d extends in the X-direction. The fourth insulating portions 19d are positioned between the conductive unit 15 and the third insulating portion 19c in the X-direction.

By providing the insulating unit 18, similarly to the seventh modification, electrons are stored in the region between the second insulating portions 18b. Also, by providing the insulating unit 19, holes are stored in the region between the fourth insulating portions 19d. The potential of each of the insulating units is affected by the stored amount of each carrier in the region where each of the insulating units is provided.

Therefore, even in the case where a difference exists between the n-type impurity concentration of the n-type semiconductor regions 2 and the p-type impurity concentration of the p-type semiconductor regions 3, it is possible to suppress the fluctuation of the electric field strength due to the concentration difference and suppress the breakdown voltage decrease of the semiconductor device.

By providing the insulating unit 19, it is possible for the holes to move easily between the p-type semiconductor regions 3 via the side walls of the insulating unit 19. Therefore, it is possible to shorten the time necessary for the depletion layers in the p-type semiconductor regions 3 to disappear when the semiconductor device is turned ON and suppress the increase of the transitional ON resistance.

### Ninth Modification

FIG. 19 is a partially enlarged plan view of a semiconductor device 290 according to a ninth modification of the second embodiment.

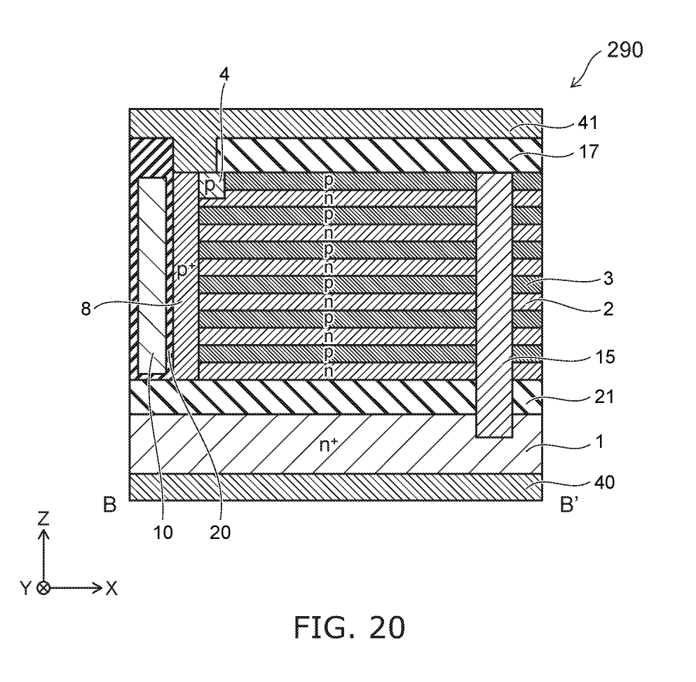

FIG. 20 is an A-A′ cross-sectional view of FIG. 19. The source electrode 41 and the insulating layer 17 are not shown in FIG. 19.

The semiconductor device 290 differs from the semiconductor device 200 in that a p⁺-type semiconductor region 8 is further included.

As shown in FIG. 19, the p⁺-type semiconductor region 8 is multiply provided in the Y-direction. Each of the p⁺-type semiconductor regions 8 is positioned between the second electrode portion 12 in the Y-direction.

As shown in FIG. 20, the p⁺-type semiconductor region 8 is provided between the gate insulating unit 20 and the stacked body LB and contacts the gate insulating unit 20. The p⁺-type semiconductor region 8 extends in the Z-direction and is electrically connected to the source electrode 41 and the multiple p-type semiconductor regions 3.

By providing the p⁺-type semiconductor region 8 that is electrically connected to the source electrode 41 and the multiple p-type semiconductor regions 3, holes are supplied to each of the p-type semiconductor regions 3 via the p⁺-type semiconductor region 8 when the semiconductor device is turned ON. In other words, according to the modification, it is possible to supply the holes to the p-type semiconductor regions 3 without providing the second gate electrode and controlling the voltage of the second gate electrode as in the third modification.

Therefore, according to the modification, using a simpler structure compared to the third modification, it is possible to shorten the time necessary for the depletion layers in the p-type semiconductor regions 3 to disappear and suppress the increase of the transitional ON resistance.

It is possible to implement the modifications according to the second embodiment described above in combination with each other.

It is also possible to appropriately implement the forms described in the second embodiment described above in combination with the forms described in the first embodiment.

It is possible to confirm the relative levels of the impurity concentrations of the semiconductor regions in the embodiments described above, for example, using a SCM (scanning capacitance microscope). The carrier concentrations of the semiconductor regions may be considered to be equal to the activated impurity concentrations of the semiconductor regions. Accordingly, the relative levels of the carrier concentrations of the semiconductor regions can be confirmed using SCM. It is possible to measure the impurity concentrations of the semiconductor regions, for example, using a SIMS (secondary ion mass spectrometer).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. One skilled in the art can appropriately select specific configurations of components included in the embodiments, for example the p-type base region 4, the n⁺-type source region 5, the insulating layer 17, the gate insulating unit 20, the drain electrode 40, and the source electrode 41 etc., from known art. The accompanying claims and their equivalents are intended to cover such forms or modifications as would fall within the scope and spirit of the invention.

What is claimed is:

1. A semiconductor device, comprising:
a first semiconductor region of a first conductivity type;
a first insulating unit provided on a portion of the first semiconductor region;
a conductive unit provided on one other portion of the first semiconductor region and connected to the first semiconductor region;
a stacked body provided on a portion of the first insulating unit, the stacked body including a plurality of second semiconductor regions of the first conductivity type and a plurality of third semiconductor regions of a second conductivity type, the plurality of second semiconductor regions being connected to the conductive unit, the plurality of third semiconductor regions being connected to the conductive unit, the plurality of second semiconductor regions being provided alternately in a first direction with the plurality of third semiconductor regions, the first direction being from the first semiconductor region toward the first insulating unit;
a fourth semiconductor region of the second conductivity type selectively provided on the stacked body;
a fifth semiconductor region of the first conductivity type selectively provided on the fourth semiconductor region;
a gate electrode provided on one other portion of the first insulating unit, the stacked body being positioned between the conductive unit and the gate electrode in a second direction perpendicular to the first direction; and
a gate insulating unit provided between the gate electrode and the stacked body, between the gate electrode and the fourth semiconductor region, and between the gate electrode and the fifth semiconductor region.

2. The device according to claim 1, further including a sixth semiconductor region of the second conductivity type provided between the stacked body and the portion of the first insulating unit in the first direction,
a carrier concentration of the second conductivity type of the sixth semiconductor region being lower than a carrier concentration of the second conductivity type of the third semiconductor regions.

3. The device according to claim 1, wherein a portion of the gate electrode is surrounded with the portion of the first insulating unit.

4. The device according to claim 1, further including a seventh semiconductor region of the first conductivity type provided between the stacked body and the gate insulating unit,
the seventh semiconductor region being connected to each of the plurality of second semiconductor regions,
a carrier concentration of the first conductivity type of the seventh semiconductor region being higher than a carrier concentration of the first conductivity type of the second semiconductor regions.

5. The device according to claim 1, wherein
the conductive unit further includes:
a first conductive unit including polycrystalline silicon; and
a second conductive unit surrounded with the first conductive unit, the second conductive unit including a metal.

6. The device according to claim 1, wherein
the gate electrode includes:
a first electrode portion extending in a third direction perpendicular to the first direction and the second direction; and
a second electrode portion multiply provided in the third direction, each of the plurality of second electrode portions extending in the second direction.

7. The device according to claim 6, wherein
the gate electrode further includes a third electrode portion extending in the second direction,
the third electrode portion is multiply provided in the third direction, and
each of the plurality of second electrode portions and each of the plurality of third electrode portions are arranged respectively in the second direction.

8. The device according to claim 1, further comprising:
a first electrode provided between the gate electrode and the conductive unit in the second direction; and
a second insulating unit provided between the first electrode and the stacked body.

9. The device according to claim 8, further comprising:
a second electrode provided under the first semiconductor region and electrically connected to the first semiconductor region; and
a third electrode provided on the fourth semiconductor region and on the fifth semiconductor region and electrically connected to the fourth semiconductor region and the fifth semiconductor region,
the first electrode being electrically connected to the second electrode.

10. The device according to claim 8, further comprising:
a second electrode provided under the first semiconductor region and electrically connected to the first semiconductor region; and
a third electrode provided on the fourth semiconductor region and on the fifth semiconductor region and electrically connected to the fourth semiconductor region and the fifth semiconductor region,
the first electrode being electrically isolated from the second electrode and the third electrode.

11. The device according to claim 10, wherein
the first electrode is multiply provided, and
the plurality of first electrodes is arranged in the second direction between the gate electrode and the conductive unit.

12. The device according to claim 1, further comprising a plurality of third insulating units provided between the gate electrode and the conductive unit in the second direction,
the plurality of third insulating units being arranged in the second direction,
each of the plurality of third insulating units including:
a first insulating portion extending in the third direction, and
a second insulating portion provided between the first insulating portion and the gate electrode in the second direction, the second insulating portion extending in the second direction and being multiply provided to be separated from each other in the third direction.

13. The device according to claim 12, further comprising a plurality of fourth insulating units provided between the gate electrode and the conductive unit in the second direction and separated from the plurality of third insulating units in the third direction,
the plurality of fourth insulating units being arranged in the second direction,
each of the plurality of fourth insulating units including:
a third insulating portion extending in the third direction, and
a fourth insulating portion provided between the first insulating portion and the conductive unit in the second direction, the fourth insulating portion extending in the second direction, the fourth insulating portion being multiply provided to be separated from each other in the third direction.

14. The device according to claim 1, further comprising an eighth semiconductor region of the second conductivity type provided between a portion of the stacked body and a portion of the gate insulating unit.

15. The device according to claim 1, wherein the gate electrode and at least a portion of the stacked body are surrounded with the conductive unit.

16. The device according to claim 1, wherein a portion of the gate electrode is surrounded with the fourth semiconductor region.
